(19) United States
(12) Patent Application Publication
(10) Pub. No.: US 2024/0183954 A1
(43) Pub. Date: Jun. 6, 2024

(54) TECHNIQUES FOR A LASER DRIVER CIRCUIT WITH ANALOG MIXER AND OFFSET

(71) Applicant: AEVA, INC., Mountain View, CA (US)

(72) Inventors: Garret Phillips, Pittsford, NY (US); Murat Ozbas, Penfield, NY (US); Bryce Bradford, Cupertino, CA (US)

(21) Appl. No.: 18/061,640

(22) Filed: Dec. 5, 2022

(51) Int. Cl. G01S 7/4912; G01S 7/4911; H03M 1/70

(52) U.S. Cl. CPC G01S 7/4912; G01S 7/4911; H03M 1/70

(57) ABSTRACT

A frequency-modulated continuous-wave (FMCW) light detection and ranging (LIDAR) system includes an optical source to generate an optical beam at a chirp rate based on a control signal. The system includes a receiver to capture at least a portion of the optical beam and generate a beat frequency based on the chirp rate. The system also includes mixer circuitry to calculate a difference value between the beat frequency and a reference frequency. The system also includes combination circuitry to combine the difference value with an offset voltage to generate an adjusted control signal that is configured to minimize the difference value to maintain the chirp rate.

### TECHNICAL FIELD

The present disclosure relates generally to light detection and ranging (LIDAR) systems, and more particularly to systems and methods of a laser driver circuit with analog mixer and offset.

### BACKGROUND

In coherent LIDAR techniques such as Frequency-Modulated Continuous-Wave radar (FMCW), both the distance and the relative radial speed of a target affects the mixing frequency between the local oscillator (LO) and the return signal. To sense both distance and speed, conventional systems using the aforementioned techniques typically use frequency modulation signals referred to as a down-chirp modulation and an up-chirp modulation. The down-chirp modulation and the up-chirp modulation can be carried within the same optical beam. Often a laser diode is used as an optical source for generating the optical beam. The laser diode generates optical energy at a wavelength that is proportional to the magnitude of the current through the laser diode. As such, modulating the current modulates the frequency of the optical energy and generates the chirps.

### SUMMARY

Laser driver circuits are often implemented via a phase locked loop (PLL) architecture to linearize the laser diode frequency output response. The PLL uses an input reference signal to dictate the rate of the laser output frequency change. The PLL must also lock (or settle) within a specific period of time if the PLL becomes un-locked. The lock time is directly proportional to the PLL loop bandwidth. Traditional PLLs may use a phase frequency detector (PFD) circuit to generate an error output signal that is proportional to the phase difference value between the phase of the feedback signal and the phase of the reference signal. With traditional phase frequency detector (PFD) circuits, however, there is a fundamental lower limit of supported reference frequencies that are based on the loop bandwidth.

Discussed herein is an approach that replaces the PFD circuitry with an analog multiplier (or mixer) and offset voltage combiner circuitry that allows for lower reference frequencies for the loop bandwidth. The combiner circuitry provides a majority of the necessary control offset or signal so that the mixer circuitry is not required to cover the entire frequency range by itself, therefore removing the limitation of locking range.

In some embodiments, the system includes an optical source to generate an optical beam at a chirp rate based on a control signal and electro optical circuitry to produce a phase locked loop (PLL) to maintain the chirp rate. The electro optical circuitry includes a receiver that captures at least a portion of the optical beam and generates a beat frequency based on the chirp rate; mixer circuitry that calculates a difference value between the beat frequency and a reference frequency; and combination circuitry that adjusts the control signal by combining the difference value with an offset voltage. The adjusted control signal is configured to minimize the difference value to maintain the chirp rate.

In some embodiments, the system includes a low pass filter coupled to the mixer circuitry and the combination circuitry that filters harmonics from passing from the mixer circuitry to the combination circuitry and stabilize the PLL.

In some embodiments, the system includes a digital to analog (DAC) converter that provides the offset voltage to the combination circuitry. In some embodiments, the system includes a controller that controls the DAC to produce a value of the offset voltage based on a lookup table that includes a list of historical average values. In some embodiments, the controller controls the DAC to produce a value of the offset voltage based on the beat frequency. In some embodiments, the controller dynamically adjusts the offset voltage in real-time during operation of the FMCW LIDAR system.

In some embodiments, an initial offset voltage is applied to the combination circuitry at initialization of the FMCW LIDAR system and then the mixer circuitry produces the difference value.

In some embodiments, an optical driver includes the electro optical circuitry. In some embodiments, the receiver includes an interferometer and a photo detector. In some embodiments, an integrated circuit includes the mixer circuitry and the combination circuitry.

These and other features, aspects, and advantages of the present disclosure will be apparent from a reading of the following detailed description together with the accompanying figures, which are briefly described below. The present disclosure includes any combination of two, three, four or more features or elements set forth in this disclosure, regardless of whether such features or elements are expressly combined or otherwise recited in a specific example implementation described herein. This disclosure is intended to be read holistically such that any separable features or elements of the disclosure, in any of its aspects and example implementations, should be viewed as combinable unless the context of the disclosure clearly dictates otherwise.

It will therefore be appreciated that this Summary is provided merely for purposes of summarizing some example implementations so as to provide a basic understanding of some aspects of the disclosure. Accordingly, it will be appreciated that the above described example implementations are merely examples and should not be construed to narrow the scope or spirit of the disclosure in any way. Other example implementations, aspects, and advantages will become apparent from the following detailed description taken in conjunction with the accompanying figures which illustrate, by way of example, the principles of some described example implementations.

### BRIEF DESCRIPTION OF THE FIGURES

Embodiments and implementations of the present disclosure will be understood more fully from the detailed description given below and from the accompanying drawings of various aspects and implementations of the disclosure, which, however, should not be taken to limit the disclosure to the specific embodiments or implementations, but are for explanation and understanding only.

FIG. 1 is a block diagram illustrating an example of a LIDAR system, according to some embodiments of the present disclosure.

FIG. 2 is a time-frequency diagram of FMCW scanning signals that can be used by a LIDAR system, according to some embodiments of the present disclosure.

FIG. 3 is a block diagram illustrating an example of a laser driver circuit for a LIDAR system, according to some embodiments of the present disclosure.

FIG. 4 is a block diagram illustrating an example of a dynamic laser driver circuit for a LIDAR system, according to some embodiments of the present disclosure.

FIG. 5 is a block diagram illustrating an example of a dynamic laser driver circuit for a LIDAR system, according to some embodiments of the present disclosure.

FIG. 6 is a flow diagram illustrating an example method of operating a frequency modulated continuous wave (FMCW) light detection and ranging (LIDAR) system, according to some embodiments of the present disclosure.

### DETAILED DESCRIPTION

According to some embodiments, the LIDAR system described herein may be implemented in any sensing market, such as, but not limited to, transportation, manufacturing, metrology, medical, virtual reality, augmented reality, and security systems. According to some embodiments, the described LIDAR system is implemented as part of a front-end of frequency modulated continuous-wave (FMCW) device that assists with spatial awareness for automated driver assist systems, or self-driving vehicles.

As discussed above, laser driver circuits are often implemented via a phase locked loop (PLL) architecture to linearize the laser diode frequency output response and the PLL uses an input reference signal to dictate the rate of the laser output frequency change. An electro optical phase locked loop (EOPLL) laser driver loop with a mixer phase detector requires a specific mixer gain and bandwidth to properly set the loop dynamics due to it being a closed loop system. The mixer gain, however, also affects the frequency range to which the mixer can lock.

Discussed herein is an approach that adds an offset voltage to the mixer output through combiner circuitry that, in turn, supports lower reference frequencies for the loop bandwidth. The offset voltage provides a majority of the necessary control offset or signal so that the mixer circuitry is not required to cover the entire frequency range by itself, therefore removing the limitation of the locking range.

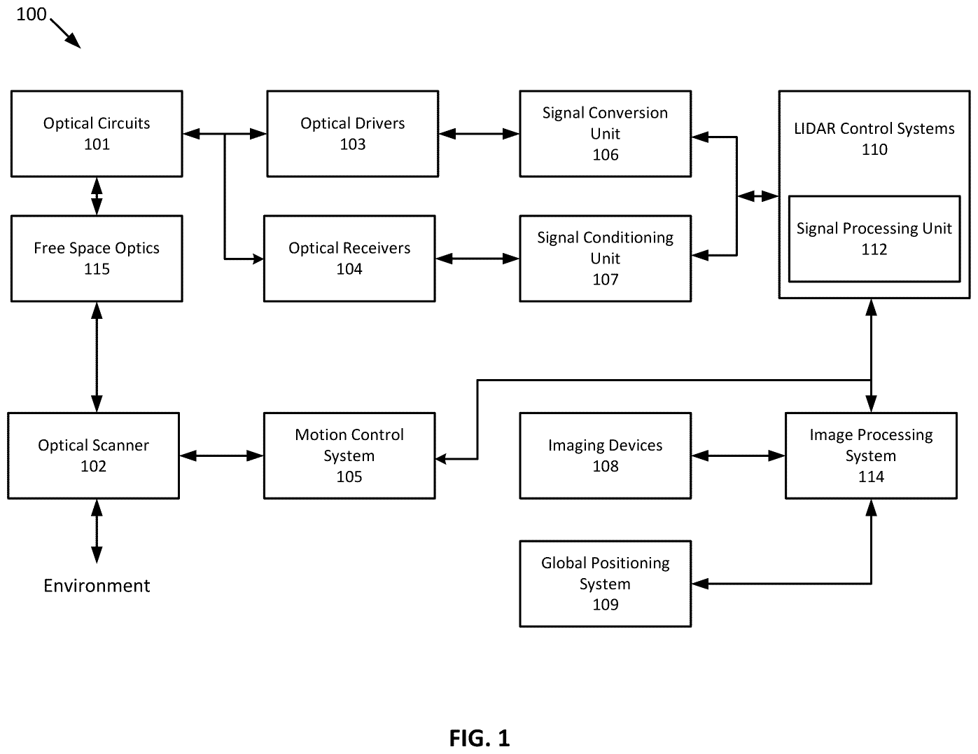

FIG. 1 is a block diagram illustrating an example of a LIDAR system, according to some embodiments. The LIDAR system 100 includes one or more of each of a number of components, but may include fewer or additional components than shown in FIG. 1. One or more of the components depicted in FIG. 1 can be implemented on a photonics chip, according to some embodiments. The optical circuits 101 may include a combination of active optical components and passive optical components. Active optical components may generate, amplify, and/or detect optical signals and the like. In some examples, the active optical component includes optical beams at different wavelengths, and includes one or more optical amplifiers, one or more optical detectors, or the like. In some embodiments, one or more LIDAR systems 100 may be mounted onto any area (e.g., front, back, side, top, bottom, and/or underneath) of a vehicle to facilitate the detection of an object in any free-space relative to the vehicle. In some embodiments, the vehicle may include a steering system and a braking system, each of which may work in combination with one or more LIDAR systems 100 according to any information (e.g., one or more rigid transformations, distance/ranging information, Doppler information, etc.) acquired and/or available to the LIDAR system 100. In some embodiments, the vehicle may include a vehicle controller that includes the one or more components and/or processors of the LIDAR system 100.

Free space optics 115 may include one or more optical waveguides to carry optical signals, and route and manipulate optical signals to appropriate input/output ports of the active optical circuit. The free space optics 115 may also include one or more optical components such as taps, wavelength division multiplexers (WDM), splitters/combiners, polarization beam splitters (PBS), collimators, couplers or the like. In some examples, the free space optics 115 may include components to transform the polarization state and direct received polarized light to optical detectors using a PBS, for example. The free space optics 115 may further include a diffractive element to deflect optical beams having different frequencies at different angles along an axis (e.g., a fast-axis).

In some examples, the LIDAR system 100 includes an optical scanner 102 that includes one or more scanning mirrors that are rotatable along an axis (e.g., a slow-axis) that is orthogonal or substantially orthogonal to the fast-axis of the diffractive element to steer optical signals to scan an environment according to a scanning pattern. For instance, the scanning mirrors may be rotatable by one or more galvanometers. Objects in the target environment may scatter an incident light into a return optical beam or a target return signal. The optical scanner 102 also collects the return optical beam or the target return signal, which may be returned to the passive optical circuit component of the optical circuits 101. For example, the return optical beam may be directed to an optical detector by a polarization beam splitter. In addition to the mirrors and galvanometers, the optical scanner 102 may include components such as a quarter-wave plate, lens, anti-reflective coated window or the like.

To control and support the optical circuits 101 and optical scanner 102, the LIDAR system 100 includes LIDAR control systems 110. The LIDAR control systems 110 may include a processing device for the LIDAR system 100. In some examples, the processing device may be one or more general-purpose processing devices such as a microprocessor, central processing unit, or the like. More particularly, the processing device may be complex instruction set computing (CISC) microprocessor, reduced instruction set computer (RISC) microprocessor, very long instruction word (VLIW) microprocessor, or processor implementing other instruction sets, or processors implementing a combination of instruction sets. The processing device may also be one or more special-purpose processing devices such as an application specific integrated circuit (ASIC), a field programmable gate array (FPGA), a digital signal processor (DSP), network processor, or the like.

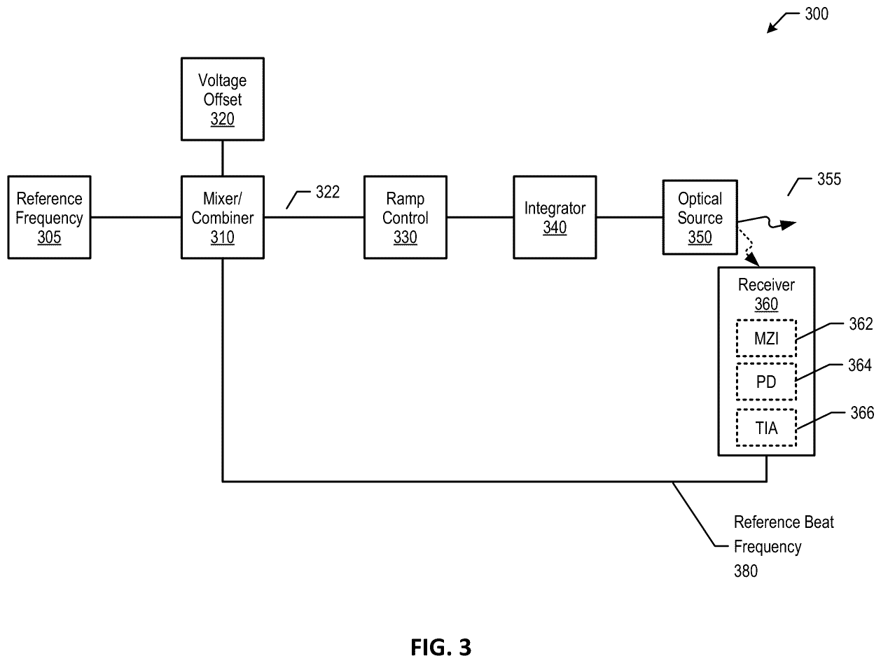

In some examples, the LIDAR control system 110 may include a processing device that may be implemented with a DSP, such as signal processing unit 112. The LIDAR control systems 110 are configured to output digital control signals to control optical drivers 103. In some examples, the digital control signals may be converted to analog signals through signal conversion unit 106. For example, the signal conversion unit 106 may include a digital-to-analog converter. The optical drivers 103 may then provide drive signals to active optical components of optical circuits 101 to drive optical sources such as lasers and amplifiers. In some examples, several optical drivers 103 and signal conversion units 106 may be provided to drive multiple optical sources. In some embodiments, optical drivers 103 includes a laser driver circuit 300 shown in FIG. 3.

The LIDAR control system 110 is also configured to output digital control signals for the optical scanner 102. A motion control system 105 may control the galvanometers of the optical scanner 102 based on control signals received from the LIDAR control systems 110. For example, a digital-to-analog converter may convert coordinate routing information from the LIDAR control systems 110 to signals interpretable by the galvanometers in the optical scanner 102. In some examples, a motion control system 105 may also return information to the LIDAR control systems 110 about the position or operation of components of the optical scanner 102. For example, an analog-to-digital converter may in turn convert information about the galvanometers' position to a signal interpretable by the LIDAR control systems 110.

The LIDAR control systems 110 are further configured to analyze incoming digital signals. In this regard, the LIDAR system 100 includes optical receivers 104 to measure one or more beams received by optical circuits 101. For example, a reference beam receiver may measure the amplitude of a reference beam from the active optical component, and an analog-to-digital converter converts signals from the reference receiver to signals interpretable by the LIDAR control systems 110. Target receivers measure the optical signal that carries information about the range and velocity of a target in the form of a beat frequency, modulated optical signal. The reflected beam may be mixed with a second signal from a local oscillator. The optical receivers 104 may include a high-speed analog-to-digital converter to convert signals from the target receiver to signals interpretable by the LIDAR control systems 110. In some examples, the signals from the optical receivers 104 may be subject to signal conditioning by signal conditioning unit 107 prior to receipt by the LIDAR control systems 110. For example, the signals from the optical receivers 104 may be provided to an operational amplifier for amplification of the received signals and the amplified signals may be provided to the LIDAR control systems 110.

In some applications, the LIDAR system 100 may additionally include one or more imaging devices 108 configured to capture images of the environment, a global positioning system 109 configured to provide a geographic location of the system, or other sensor inputs. The LIDAR system 100 may also include an image processing system 114. The image processing system 114 can be configured to receive the images and geographic location, and send the images and location or information related thereto to the LIDAR control systems 110 or other systems connected to the LIDAR system 100.

In operation according to some examples, the LIDAR system 100 is configured to use nondegenerate optical sources to simultaneously measure range and velocity across two dimensions. This capability allows for real-time, long range measurements of range, velocity, azimuth, and elevation of the surrounding environment.

In some examples, the scanning process begins with the optical drivers 103 and LIDAR control systems 110. The LIDAR control systems 110 instruct, e.g., via signal processor unit 112, the optical drivers 103 to independently modulate one or more optical beams, and these modulated signals propagate through the optical circuits 101 to the free space optics 115. The free space optics 115 directs the light at the optical scanner 102 that scans a target environment over a preprogrammed pattern defined by the motion control system 105. The optical circuits 101 may also include a polarization wave plate (PWP) to transform the polarization of the light as it leaves the optical circuits 101. In some examples, the polarization wave plate may be a quarter-wave plate or a half-wave plate. A portion of the polarized light may also be reflected back to the optical circuits 101. For example, lensing or collimating systems used in LIDAR system 100 may have natural reflective properties or a reflective coating to reflect a portion of the light back to the optical circuits 101.

Optical signals reflected back from an environment pass through the optical circuits 101 to the optical receivers 104. Because the polarization of the light has been transformed, it may be reflected by a polarization beam splitter along with the portion of polarized light that was reflected back to the optical circuits 101. In such scenarios, rather than returning to the same fiber or waveguide serving as an optical source, the reflected signals can be reflected to separate optical receivers 104. These signals interfere with one another and generate a combined signal. The combined signal can then be reflected to the optical receivers 104. Also, each beam signal that returns from the target environment may produce a time-shifted waveform. The temporal phase difference value between the two waveforms generates a beat frequency measured on the optical receivers 104 (e.g., photodetectors).

The analog signals from the optical receivers 104 are converted to digital signals by the signal conditioning unit 107. These digital signals are then sent to the LIDAR control systems 110. A signal processing unit 112 may then receive the digital signals to further process and interpret them. In some embodiments, the signal processing unit 112 also receives position data from the motion control system 105 and galvanometers (not shown) as well as image data from the image processing system 114. The signal processing unit 112 can then generate 3D point cloud data (sometimes referred to as, “a LIDAR point cloud”) that includes information about range and/or velocity points in the target environment as the optical scanner 102 scans additional points. In some embodiments, a LIDAR point cloud may correspond to any other type of ranging sensor that is capable of Doppler measurements, such as Radio Detection and Ranging (RADAR). The signal processing unit 112 can also overlay 3D point cloud data with image data to determine velocity and/or distance of objects in the surrounding area. The signal processing unit 112 also processes the satellite-based navigation location data to provide data related to a specific global location.

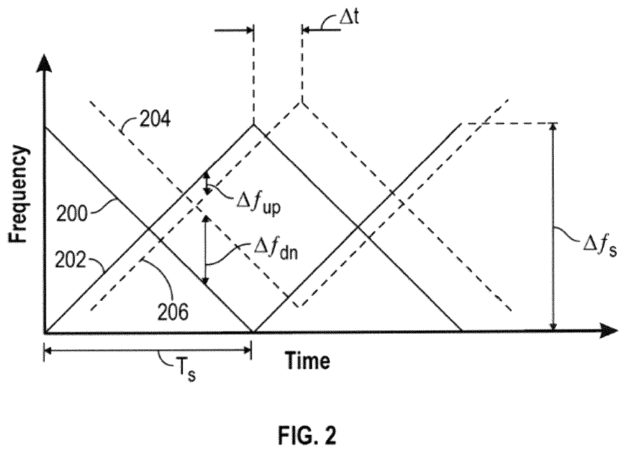

FIG. 2 is a time-frequency diagram of FMCW scanning signals that can be used by a LIDAR system according to some embodiments of the present disclosure. The FMCW scanning signals 200 and 202 may be used in any suitable LIDAR system, including the system 100, to scan a target environment. The scanning signal 200 may be a triangular waveform with an up-chirp and a down-chirp having a same bandwidth Δfₛ and period Tₛ. The other scanning signal 202 is also a triangular waveform that includes an up-chirp and a down-chirp with bandwidth Δfₛ and period Tₛ. However, the two signals are inverted versions of one another such that the up-chirp on scanning signal 200 occurs in unison with the down-chirp on scanning signal 202.

FIG. 2 also depicts example return signals 204 and 206. The return signals 204 and 206, are time-delayed versions of the scanning signals 200 and 202, where Δₜ is the round trip time to and from a target illuminated by scanning signal 201. The round trip time is given as Δt=2R/v, where R is the target range and v is the velocity of the optical beam, which is the speed of light c. The target range, R, can therefore be calculated as R=c(Δt/2).

In embodiments, the time delay Δt is not measured directly, but is inferred based on the frequency difference values between the outgoing scanning waveforms and the return signals. When the return signals 204 and 206 are optically mixed with the corresponding scanning signals, a signal referred to as a “beat frequency” is generated, which is caused by the combination of two waveforms of similar but slightly different frequencies. The beat frequency indicates the frequency difference value between the outgoing scanning waveform and the return signal, which is linearly related to the time delay Δt by the slope of the triangular waveform.

If the return signal has been reflected from an object in motion, the frequency of the return signal will also be effected by the Doppler effect, which is shown in FIG. 2 as an upward shift of the return signals 204 and 206. Using an up-chirp and a down-chirp enables the generation of two beat frequencies, Δfᵤₚ and Δfₐₙ. The beat frequencies Δfᵤₚ and Δfₐₙ are related to the frequency difference value cause by the range, Δf_{Range}, and the frequency difference value cause by the Doppler shift, Δf_{Doppler}, according to the following formulas:

Δfᵤₚ=Δf_{Range}−Δf_{Doppler} (1)

Δfₐₙ=Δf_{Range}+Δf_{Doppler} (2)

Thus, the beat frequencies Δfᵤₚ and Δfₐₙ can be used to differentiate between frequency shifts caused by the range and frequency shifts caused by motion of the measured object. Specifically, Δf_{Doppler} is the difference value between the Δfᵤₚ and Δf_{dn} and the Δf_{Range} is the average of Δfᵤₚ and Δf_{dn}.

The range to the target and velocity of the target can be computed using the following formulas:

$$Range = Δ {f}_{R a n g e} \frac{c {T}_{s}}{2 Δ {f}_{s}} \qquad ( 3 )$$

$$Velocity = Δ {f}_{Doppler} \frac{{λ}_{c}}{2} \qquad ( 4 )$$

In the above formulas, λ_{c}=c/f_{c} and f_{c} is the center frequency of the scanning signal. The beat frequencies can be generated, for example, as an analog signal in optical receivers 104 of system 100. The beat frequency can then be digitized by an analog-to-digital converter (ADC), for example, in a signal conditioning unit such as signal conditioning unit 107 in LIDAR system 100. The digitized beat frequency signal can then be digitally processed, for example, in a signal processing unit, such as signal processing unit 112 in system 100.

In some scenarios, to ensure that the beat frequencies accurately represent the range and velocity of the object, beat frequencies can be measured at a same moment in time, as shown in FIG. 2. Otherwise, if the up-chirp beat frequency and the down-chirp beat frequencies were measured at different times, quick changes in the velocity of the object could cause inaccurate results because the Doppler effect would not be the same for both beat frequencies, meaning that equations (1) and (2) above would no longer be valid. In order to measure both beat frequencies at the same time, the up-chirp and down-chirp can be synchronized and transmitted simultaneously using two signals that are multiplexed together.

FIG. 3 is a block diagram illustrating an example of a laser driver circuit for LIDAR system 100, according to some embodiments of the present disclosure. Components of laser driver circuit 300 may be included within the optical drivers 103 shown in FIG. 1. In some embodiments, laser driver circuit 300 may be implemented within optical drivers 103 as a single integrated circuit chip, as separate discrete circuit elements, or as a combination of discrete circuit elements and one or more integrated circuit chips. In some embodiments, optical source 350 and receiver 360 (or portions thereof) are implemented as discrete circuit components mounted, for example, to a circuit board such as printed circuit board (PCB), while the mixer/combiner 310, voltage offset 320, ramp control 330, integrator 340, and other portions of receiver 360 are implemented in an integrated circuit chip (e.g., silicon wafer). Other embodiments are also possible.

Laser driver circuit 300 includes an optical source 350 configured to emit laser light (e.g., optical beam) for performing LIDAR-based range and velocity detection. The optical beam may be a frequency-modulated continuous wave (FMCW) optical beam that is modulated according to a particular chirp rate. It should be appreciated that the optical beam output by the optical source may be referred to herein as an outgoing, transmitted, or incident beam, while the beam reflected from the target may be referred to herein as an incoming, received, or return beam.

As shown in FIG. 3, at least a portion of the optical beam 355 transmitted from optical source 350 is captured by receiver 360 for use by one or more components resident on Lidar system 100 to generate reference beat frequency 380. In some embodiments, receiver 360 includes an optical interferometer (362), a photo detector (364), and may also include a transimpedance amplifier 366. In some embodiments, the optical interferometer and the photo detector are implemented as discrete components, while the transimpedance amplifier is implemented in an integrated circuit.

In some embodiments, the optical interferometer 362 captures the portion of the optical beam from optical source 350, which may be a Mach-Zehnder Interferometer (MZI), for example. The optical interferometer splits the light from the optical beam into two different length paths, and then recombines the light into a single path. Any instantaneous difference value in frequency of the two recombined light signals shows up as a reference beat frequency, which corresponds to the chirp rate produced by optical source 350. The beat frequency is detected by the photodetector 364, which may be a photodiode followed by the transimpedance amplifier (TIA) 366 that converts the current signal from the photodiode into a voltage (e.g., reference beat frequency 380). Receiver 360 transmits the reference beat frequency 380 back to mixer/combiner 310 for use as a voltage feedback signal. In this fashion, mixer/combiner 310 can use reference beat frequency 380 to determine the rate of change in the frequency of the light emitted by optical source 350.

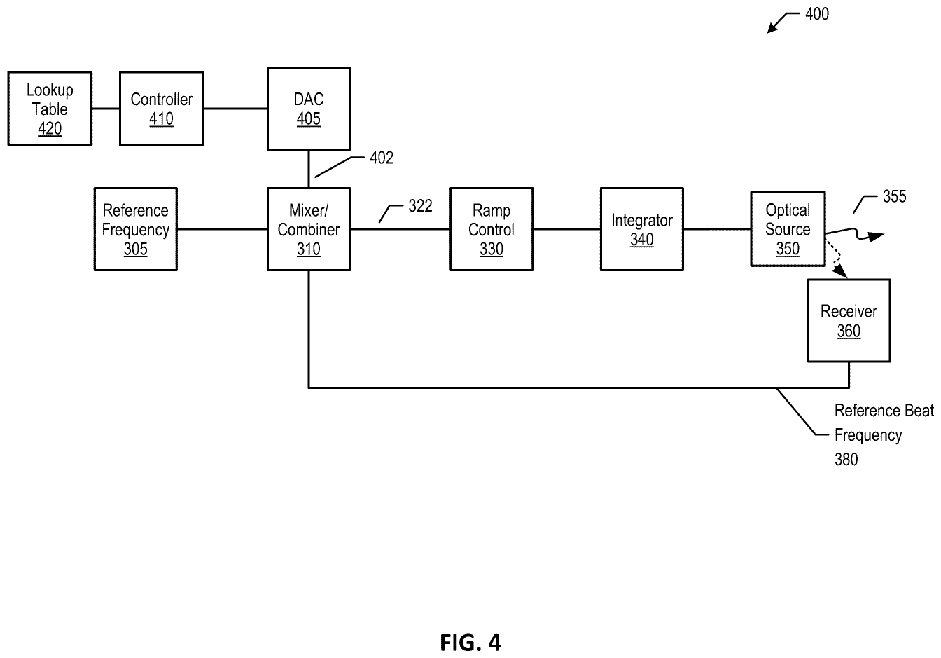

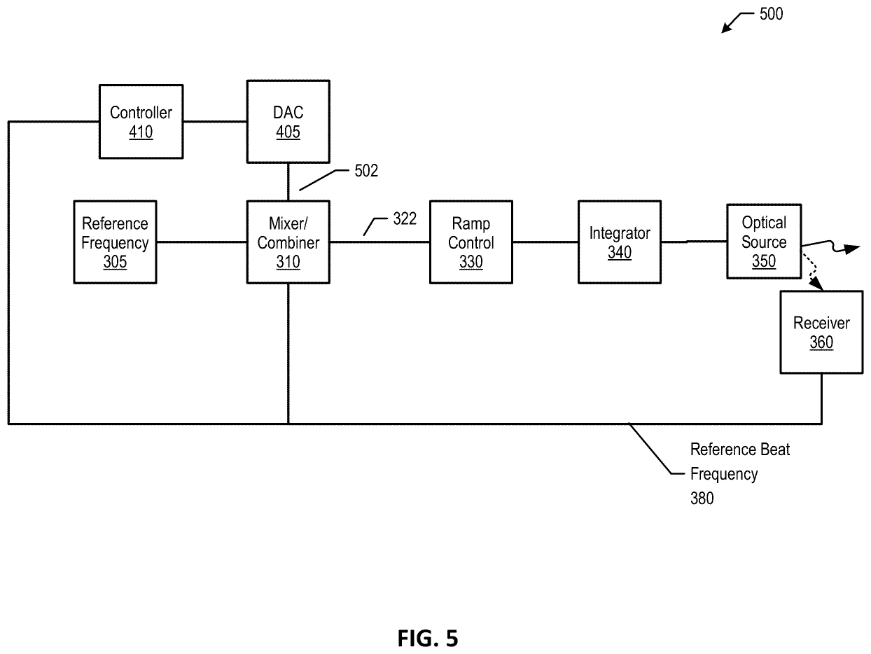

In some embodiments, reference frequency 305 can be a predetermined chirp rate of LIDAR control systems 110. In some embodiments, mixer/combiner 310 includes an analog mixer that generates an output based on a phase difference value between reference beat frequency 380 and reference frequency 305. In some embodiments, mixer/combiner 310 includes a low pass filter and combination circuitry. In this fashion, mixer/combiner 310 includes the functionality to filter out harmonics, noise, etc., generated by the mixer to stabilize laser driver circuit 300. The combination circuitry combines the filtered difference value signal with voltage offset 320 to produce a control signal 322. In some embodiments, an analog-to-digital controller (ADC) produces voltage offset 320 (see FIGS. 4, 5, and corresponding text for further details).

Without the voltage offset 320, the mixer would have to produce the control signal XXX alone (e.g., supply the entire voltage for the control signal), which would reduce the mixer's dynamic range, reduce its frequency locking range, and lead to instabilities when the required amount of frequency correction is beyond what remains after the offset is established. In some embodiments, laser driver circuit 300 combines voltage offset 320 in parallel with the mixer to allow the mixer to focus its entire dynamic range on reducing that difference value between reference beat frequency 380 and reference frequency 305. In some embodiments, voltage offset 320 may be a static value or a dynamic value, such as embodiments shown in FIGS. 4 and 5, to further reduce the mixer burden when a periodic signal is useful.

In some embodiments, the output of mixer/combiner 310 feeds into ramp control 330. Ramp control 330 is configured to cause the output of mixer/combiner 310 to pass the control signal 322 or inverted polarity of the control signal 322 based on ramp_up switches and ramp_down switches. Proper control of the ramp control switches cause integrator 340 to generate a signal pattern, including a sawtooth pattern or the triangular pattern shown in FIG. 2, for example. Integrator 340 includes the functionality to produce output voltages that are proportional to an input voltage integrated over time. In some embodiments, instead of or in addition to feeding into mixer/combiner 310, voltage offset 320 is sent as input to integrator 340 which in turn provides the functionality to add (e.g., sum, combine, total, etc.) voltage offset 320 to the output of ramp control 330.

It will be appreciated that various alterations may be made to laser driver circuit 300 and that some components may be omitted or added without departing from the scope of the disclosure.

FIG. 4 is a block diagram illustrating an example of a dynamic laser driver circuit for LIDAR system 100, according to some embodiments of the present disclosure. FIG. 4 is similar to FIG. 3 with the addition of lookup table 420, controller 410, and digital to analog converter (DAC) 405 replacing voltage offset 320. In some embodiments, DAC 405, controller 410, and lookup table 420 are included in an integrated circuit.

Laser driver circuit 400 includes an optical source 350 configured to emit laser light (e.g., optical beam) for performing LIDAR-based range and velocity detection. The optical beam may be a frequency-modulated continuous wave (FMCW) optical beam that is modulated according to a particular chirp rate.

As shown in FIG. 4, at least a portion of the optical beam 355 transmitted from optical source 350 is captured by receiver 360 for use by one or more components resident on Lidar system 100 to generate reference beat frequency 380. Receiver 360 transmits the reference beat frequency 380 back to mixer/combiner 310 for use as a voltage feedback signal. In this fashion, mixer/combiner 310 can use reference beat frequency 380 to determine the rate of change in the frequency of the light emitted by optical source 350.

Mixer/combiner 310 combines reference beat frequency 380 with a voltage offset 402 produced by DAC 405, which is controlled by controller 410, to produce control signal 322. In some embodiments, controller 410 includes the functionality to access lookup table 420 to determine input bit values to provide to DAC 405. In some embodiments, the values in lookup table 420 are based on historical values of multiple sweeps of laser driver circuit 400. Controller 410 sets DAC 405 to an initial offset voltage at initialization of LIDAR system 100, and then adjusts the input values of DAC 405 accordingly.

Control signal 322 feeds into ramp control 330. Ramp control 330 is configured to cause the output of mixer/combiner 310 to pass the control signal 322 or inverted polarity of the control signal 322 based on ramp_up switches and ramp_down switches. Proper control of the ramp control switches cause integrator 340 to generate a signal pattern, including a sawtooth pattern or the triangular pattern shown in FIG. 2, for example. Integrator 340 includes the functionality to produce output voltages that are proportional to an input voltage integrated over time that feed into optical source 350.

FIG. 5 is a block diagram illustrating an example of a dynamic laser driver circuit for LIDAR system 100, according to some embodiments of the present disclosure. Laser driver circuit 500 is similar to laser driver circuit 400 in FIG. 4 with the exception that controller 410 adjusts control signals to DAC 405 based on reference beat frequency 380 instead of lookup table 420.

Laser driver circuit 500 includes an optical source 350 configured to emit laser light (e.g., optical beam) for performing LIDAR-based range and velocity detection. The optical beam may be a frequency-modulated continuous wave (FMCW) optical beam that is modulated according to a particular chirp rate. As shown in FIG. 5, at least a portion of the optical beam 355 transmitted from optical source 350 is captured by receiver 360 for use by one or more components resident on Lidar system 100 to generate reference beat frequency 380.

As discussed above, reference beat frequency 380 feeds into controller 410, which uses reference beat frequency 380 as a basis for adjusting DAC 405. As such, controller 410 is able to perform adjustments in real-time to DAC 405 and reduce the burden on the mixer in mixer/combiner 310. Reference beat frequency 380 also feeds into mixer/combiner 310 for use as a voltage feedback signal. Mixer/combiner 310 combines reference beat frequency 380 with the voltage offset 502 to produce control signal 322.

Control signal 322 feeds into ramp control 330. Ramp control 330 is configured to cause the output of mixer/combiner 310 to pass the control signal 322 or inverted polarity of the control signal 322 based on ramp_up switches and ramp_down switches. Proper control of the ramp control switches cause integrator 340 to generate a signal pattern, including a sawtooth pattern or the triangular pattern shown in FIG. 2, for example. Integrator 340 includes the functionality to produce output voltages that are proportional to an input voltage integrated over time that feed into optical source 350.

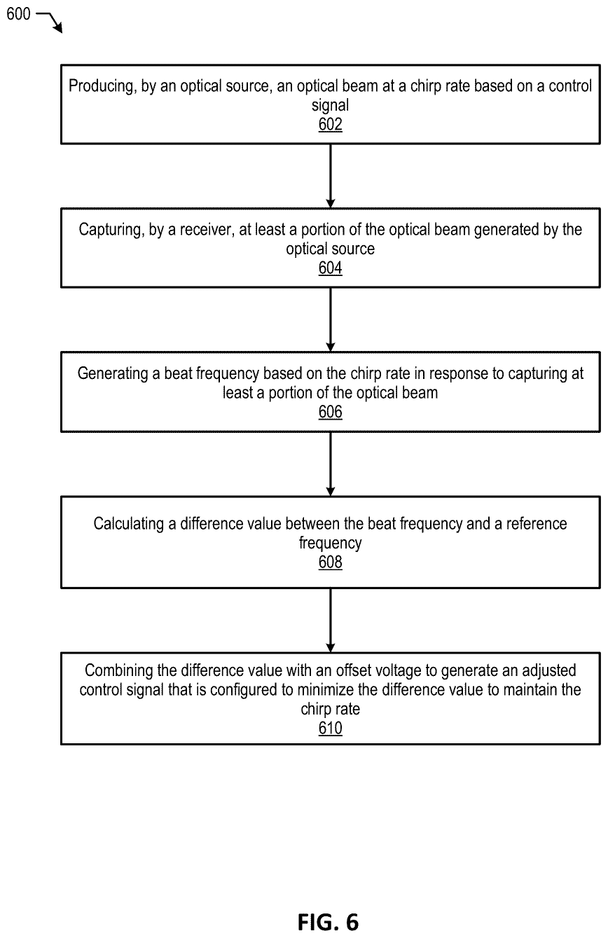

FIG. 6 is a flow diagram illustrating an example method of operating a frequency modulated continuous wave (FMCW) light detection and ranging (LIDAR) system, according to some embodiments of the present disclosure. The method 600 may be performed by any suitable LIDAR system and various components, including the LIDAR system 100, and laser driver circuits 300, 400, or 500 included in optical drivers 103 described above. Additional, fewer, or different operations may be performed in the method depending on the particular arrangement. In some embodiments, some or all operations of method 600 may be performed by one or more processors executing on one or more computing devices, systems, or servers (e.g., remote/networked servers or local servers).

In some embodiments, method 600 may be performed by a signal processing unit, such as signal processing unit 112 in FIG. 1. Each operation may be re-ordered, added, removed, or repeated. In some embodiments, method 600 may be performed by processing logic including hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof.

In some embodiments, the method 800 may include operation 602 of producing, by an optical source, such as optical source 350 included in laser driver circuits 300, 400, or 500, an optical beam at a chirp rate based on a control signal.

In some embodiments, the method 800 may include operation 604 of capturing, by a receiver such as receiver 360 included in laser driver circuits 300, 400, or 500, at least a portion of the optical beam generated by the optical source. In some embodiments, the receiver may be an interferometer, a photo diode, and may also include a transimpedance amplifier.

In some embodiments, the method 800 may include operation 606 of generating a beat frequency based on the chirp rate in response to capturing at least a portion of the optical beam. In some embodiments, the beat frequency is generated by receiver 360 shown in laser driver circuits 300, 400, or 500 in FIG. 3, 4, or 5, respectively.

In some embodiments, the method 800 may include operation 608 of calculating a difference value between the beat frequency and a reference frequency, such as by mixer circuitry in mixer/combiner 310 shown in laser driver circuits 300, 400, or 500 in FIG. 3, 4, or 5, respectively. In some embodiments, the method 800 may include operation 610 of adjusting the control signal by combining the difference value with an offset voltage, such as by combination circuitry in mixer/combiner 310 shown in laser driver circuits 300, 400, or 500 in FIG. 3, 4, or 5, respectively. The adjusted control signal is configured to minimize the difference value to maintain the chirp rate.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. While this specification contains many specific implementation details, these should not be construed as limitations on the scope of any embodiment of the present disclosure or of what may be claimed, but rather as descriptions of features specific to particular embodiments of the present disclosure. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination. Moreover, the separation of various system components in the embodiments described above should not be understood as requiring such separation in all embodiments, and it should be understood that the described program components and systems can generally be integrated together in a single software product or packaged into multiple software products. Particular embodiments may vary from these exemplary details and still be contemplated to be within the scope of the present disclosure.

Reference throughout this specification to “one embodiment” or “an embodiment” means that a particular feature, structure, or characteristic described in connection with the embodiments included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.”

Although the operations of the methods herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be in an intermittent or alternating manner.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an implementation” or “one implementation” throughout is not intended to mean the same embodiment or implementation unless described as such. Furthermore, the terms “first,” “second,” “third,” “fourth,” etc. as used herein are meant as labels to distinguish among different elements and may not necessarily have an ordinal meaning according to their numerical designation.

What is claimed is:

1. A frequency modulated continuous wave (FMCW) light detection and ranging (LIDAR) system, comprising:
an optical source to generate an optical beam at a chirp rate based on a control signal;
a receiver to capture at least a portion of the optical beam and generates a beat frequency based on the chirp rate;
mixer circuitry to produce a difference value between the beat frequency and a reference frequency; and
combination circuitry to combine the difference value with an offset voltage to generate an adjusted control signal, wherein the adjusted control signal is configured to minimize the difference to maintain the chirp rate.

2. The FMCW LIDAR system of claim 1, wherein electro optical circuitry comprises the receiver, the mixer circuitry, and the combination circuitry to produce a phase locked loop (PLL) that maintains the chirp rate at the reference frequency.

3. The FMCW LIDAR system of claim 2, wherein the electro optical circuitry further comprises:
a low pass filter coupled to the mixer circuitry and the combination circuitry to filter harmonics from passing from the mixer circuitry to the combination circuitry and stabilize the PLL.

4. The FMCW LIDAR system of claim 2, wherein the electro optical circuitry further comprises:
a digital to analog (DAC) converter to provide the offset voltage to the combination circuitry.

5. The FMCW LIDAR system of claim 4, wherein a controller controls the DAC to produce a value of the offset voltage based on a lookup table, wherein the lookup table comprises a list of historical average values.

6. The FMCW LIDAR system of claim 5, wherein the controller controls the DAC to produce a level of the offset voltage based on the beat frequency.

7. The FMCW LIDAR system of claim 5, wherein the controller dynamically adjusts the offset voltage in real-time during operation of the FMCW LIDAR system.

8. The FMCW LIDAR system of claim 4, wherein the DAC provides an initial offset voltage to the combination circuitry at initialization of the FMCW LIDAR system, and wherein the mixer circuitry produces the difference value in response to the provided initial offset voltage.

9. The FMCW LIDAR system of claim 2, wherein an optical driver comprises the electro optical circuitry.

10. The FMCW LIDAR system of claim 1, wherein the receiver comprises an interferometer and a photo detector.

11. The FMCW LIDAR system of claim 1 wherein an integrated circuit comprises the mixer circuitry and the combination circuitry.

12. A method of operating a frequency modulated continuous wave (FMCW) light detection and ranging (LIDAR) system, comprising:
producing, by an optical source, an optical beam at a chirp rate based on a control signal;
capturing, by a receiver, at least a portion of the optical beam generated by the optical source;
generating a beat frequency based on the chirp rate responsive to capturing the at least portion of the optical beam;
calculating a difference value between the beat frequency and a reference frequency; and
combining the difference value with an offset voltage to generate an adjusted control signal, wherein the adjusted control signal is configured to minimize the difference value to maintain the chirp rate.

13. The method of claim 12, further comprising:
filtering a set of harmonics generated from the combining of the difference value with the offset voltage.

14. The method of claim 13, further comprising:
controlling, by a controller, a digital to analog converter (DAC) to produce a level of the offset voltage based on a lookup table, wherein the lookup table comprises a list of historical average values.

15. The method of claim 13, further comprising:
controlling, by a controller, a digital to analog converter (DAC) to produce a value of the offset voltage based on the beat frequency.

16. A frequency-modulated continuous wave (FMCW) light detection and ranging (LIDAR) system, the FMCW LIDAR system comprising:
an optical source to transmit a plurality of optical beams towards a target;
a memory to store a set of instructions; and
a processor coupled to the memory that, when executing the set of instructions, is configured to:
produce, by the optical source, the optical beam at a chirp rate based on a control signal;
generate a beat frequency based on the chirp rate in response to capturing at least a portion of the optical beam;
calculate a difference value between the beat frequency and a reference frequency; and
adjust the control signal by combining the difference value with an offset voltage, wherein the adjusted control signal is configured to minimize the difference value to maintain the chirp rate.

17. The system of claim 16, wherein the processor is configured to filter a set of harmonics generated from the combining of the difference value with the offset voltage.

18. The system of claim 16, wherein the processor is configured to control a digital to analog converter (DAC) to produce a value of the offset voltage based on a lookup table, wherein the lookup table comprises a list of historical average values.

19. The system of claim 16, wherein the processor is configured to control a digital to analog converter (DAC) to produce a level of the offset voltage based on the beat frequency.

20. The system of claim 16 wherein the processor is configured to dynamically adjust the offset voltage in real-time during operation of the FMCW LIDAR system.
